(19) United States
(12) Patent Application Publication
(10) Pub. No.: US 2026/0334251 A1
(43) Pub. Date: Oct. 22, 2026

(54) 2.5D PACKAGING STRUCTURE AND PREPARATION METHOD

(71) Applicant: SJ Semiconductor(Jiangyin) Corporation, Jiangyin (CN)

(72) Inventors: Yenheng CHEN, Jiangyin (CN); Chengchung LIN, Jiangyin (CN); Jin YANG, Jiangyin (CN)

(73) Assignee: SJ Semiconductor(Jiangyin) Corporation, Jiangyin, JS (CN)

(21) Appl. No.: 19/107,591

(22) PCT Filed: Jun. 8, 2023
(86) PCT No.: PCT/CN2023/099207

§ 371 Date: Feb. 28, 2025

(30) Foreign Application Priority Data
Sep. 1, 2022 (CN) 202211065444.4

(51) Int. Cl. H10W 70/60; H10W 70/05; H10W 74/10; H10W 90/00; H10W 90/10

(52) U.S. Cl. CPC H10W 70/618; H10W 70/05; H10W 74/117; H10W 90/10; H10W 90/401

(57) ABSTRACT

The present invention provides a 2.5D encapsulation structure and preparation method. The structure includes an electrically connected adapter plate, a chip, and an encapsulation layer in an encapsulation body. Multiple independently set encapsulation bodies are electrically connected through connection bridges to form an interconnected encapsulation body, and then electrically connected to a substrate. So multiple small-sized adapter plates can be electrically connected to each other through the connection bridges to form a larger-sized adapter plate. Results are increases in bandwidth and reductions in inter-chip delays. This method can reduce the difficulty of preparing large-sized adapter plates, thereby reducing costs and improving yields.

### TECHNICAL FIELD

The present invention relates to the field of semiconductors, and in particular to a 2.5D package structure and a preparation method.

### BACKGROUND

Semiconductor integrated circuits (IC) industry has undergone rapid development. Packaging as a very critical part of the IC manufacturing plays an important role in the performance of chips, it not only does placing, fixing, sealing, and protecting chips, and also plays a role in the IC chip bonding point and a role of external electrical connection, thereby enhancing the electrical and thermal properties.

In today's high-end chip packaging filed, silicon adapter plates are widely used in the packaging process in order to form high-density electrical pathways with fine details among chips. The size of the adapter plates is also continuously increasing especially with the demand for high bandwidth and low latency in high-performance chips. Based on the current technology, it is difficult to construct a large-size adapter plate with a high yield rate, so the cost of forming large-size adapter plates is high.

### SUMMARY

To overcome the drawbacks of the current technique, the present disclosure provides a 2.5D encapsulated structure and a preparation method for making large-sized adapter plates.

The method of preparing a 2.5D encapsulated structure comprises the following steps:
providing an adapter plate, the adapter plate has a first side and an opposing second side;
affixing a chip on the first side of the adapter plate and the adapter plate is electrically connected to the chip;
forming an encapsulation layer, the encapsulation layer covers the chip and the first side of the adapter plate to form an encapsulant;
providing a temporary carrier sheet to bond at least two of the encapsulants to the temporary carrier sheet and to reveal a second side of the adapter plate;
bonding a connecting bridge to the second side of the adapter plate, the connecting bridge is electrically connected to the adapter plate to interconnect the encapsulants to form an interconnect package; and
providing a substrate, bonding the interconnect package to the substrate, and the second side of the adapter plate is electrically connected to the substrate.

Optionally, prior to bonding the interconnect package to the substrate, the method further includes a step of forming a recess in the substrate to accommodate the connecting bridge through the recess, wherein the step of forming the recess can be a laser drilling process.

Optionally, the connecting bridge comprises a glass connecting bridge and/or a silicon connecting bridge, and the step of bonding the connecting bridge includes a hot press bonding process.

Optionally, the second side of the adapter plate and/or the surface of the substrate forms a metallic interconnect, the step of bonding the interconnect package and the substrate includes a reflow process or a hot press bonding process.

Optionally, the connecting bridge formed is electrically connected to the substrate.

Optionally, forming the encapsulation layer is followed by a step of grinding the encapsulation layer to reveal the chip.

Optionally, after forming the connecting bridge and before or after bonding the substrate, the method further comprises a step of removing the temporary carrier sheet.

The present invention also provides a 2.5D package structure, the 2.5D package structure comprises:
an adapter plate comprising a first side and an opposing second side;
chips disposed on the first side of the adapter plate, and the adapter plate being electrically connected to the chips;
an encapsulation layer, the encapsulation layer covers the chips and the first side of the adapter plate, such that the adapter plate, the chips and the encapsulation layer are combined to form encapsulants;
a connecting bridge disposed on a second side of the adapter plate, the connecting bridge is electrically connected to the adapter plate to interconnect the encapsulants, and the interconnected encapsulants in combination with the connecting bridge constitute an interconnect package; and
a substrate disposed below the interconnect packages, and the second side of the adapter plate is electrically connected to the substrate.

Optionally, the connecting bridge is a silicon and/or glass bridge.

Optionally, the substrate is further provided with a recess for accommodating the connecting bridge.

As described above, the 2.5D package structure and preparation method of the present invention have the following beneficial effects: first preparing an encapsulant body including an electrically connected adapter plate, a chip, and an encapsulation layer, electrically connecting independently such packages through a connecting bridge to form an interconnect package, then electrically connecting to a substrate, so that a number of small-sized adapter plates can be electrically connected to each other to form a larger-sized adapter plate through the connecting bridge. Thus, this structure realizes increased bandwidth and reduced inter-chip delays, thereby reducing the difficulty of preparing large-sized adapter plates, reducing costs, and improving yields. The bridges are used to electrically connect multiple small-sized adapter plates together to form a larger-sized adapter plate.

### BRIEF DESCRIPTION OF THE DRAWINGS

FIG. 1 illustrates a flow chart of a preparation method for a 2.5D encapsulated structure according to an embodiment of the present invention.

FIG. 2 shows a schematic cross-sectional view of the adapter plate according to Embodiment 1 of the present invention.

FIG. 3 shows a schematic cross-sectional view after placement of a chip according to Embodiment 1 of the present invention.

FIG. 4 shows a schematic cross-sectional view after forming the encapsulation layer according to Embodiment 1 of the present invention.

FIG. 5 shows a schematic cross-sectional view after thinning of the encapsulation layer according to Embodiment 1 of the present invention.

FIG. 6 shows a schematic top view after bonding the temporary carrier sheet according to Embodiment 1 of the present invention.

FIG. 7 shows a schematic cross-sectional view of the connection bridge after forming the connection bridge and removing the temporary carrier sheet according to Embodiment 1 of the present invention.

FIG. 8 shows a schematic cross-sectional view of one 2.5D package structure according to Embodiment 1 of the present invention.

FIG. 9 shows a schematic cross-sectional view of another 2.5D package structure according to another Embodiment 1 of the present invention.

### REFERENCE NUMERALS

101: an adapter plate, 1011: a metal interconnect, 1012: a first side, 1013: a second side, 102: a chip, 1021: a first chip, 1022: a second chip, 103: an encapsulation layer, 104: an encapsulant, 105: a temporary carrier sheet, 106: a connection bridge, 107: a metal wiring layer, 108: an interconnect encapsulant, 109: a metal interconnect, 110: substrate, 111: recess, S1~S6: steps.

### DETAILED DESCRIPTION OF THE PREFERRED EMBODIMENTS

The specific embodiments are described below to illustrate the implementation of the present disclosure, and those skilled in the art can easily understand other advantages and effects of the present disclosure from the content disclosed in this specification. The present disclosure can also be implemented or applied in other specific embodiments. The details provided in this description can be modified or altered in various ways based on different perspectives and applications without departing from the spirit of the present disclosure.

For ease of description, spatial relationship terms such as “under,” “below,” “below,” “below,” “above,” etc. may be used herein to describe the relationship of an element or feature shown in the accompanying drawings to other elements or features. “above”, etc. to describe the relationship of one element or feature to other elements or features shown in the accompanying drawings. It will be appreciated that these spatial relationship terms are intended to encompass orientations of the device in use or operation other than those depicted in the accompanying drawings. Furthermore, when a layer is to be “between” two layers, it may be the only layer between the two layers, or there may be one or more intervening layers.

It is to be understood that the use of terms such as “first” and “second” to qualify the parts is only for the purpose of facilitating the differentiation of the parts, and the terms do not have special meanings if not otherwise declared, and therefore cannot be construed as a limitation of the scope of protection of the present invention. Therefore, they cannot be construed as a limitation of the scope of protection of the present invention.

Refer to FIGS. 1 through 9. It is to be noted that the illustrations provided in this embodiment only illustrate the basic concept of the present invention in a schematic manner so that the illustrations only show the components related to the present invention and are not drawn in accordance with the actual implementation of the number of components, shapes and sizes of the actual implementation of the components of the type, number and proportion of the actual implementation of the components may be an arbitrary change, and the layout of the components of the type may be more complex.

### Embodiment 1

Referring to FIGS. 1 to 9, the present invention provides a method of preparing a 2.5D encapsulated structure, and the method comprises the following steps:

S1: providing an adapter plate 101, the adapter plate 101 comprises a first side 1012 and an opposite second side 1013;

S2: affixing a chip 102 on a first side 1012 of the adapter plate, and the adapter plate 101 being electrically connected to the chip 102;

S3: forming an encapsulation layer 103, the encapsulation layer 103 covers the chip 102 and the first side 1012 of the adapter plate to form an encapsulant 104;

S4: providing a temporary carrier sheet 105, bonding at least two of the encapsulants 104 to the temporary carrier sheet 105 and revealing a second side 1013 of the adapter plate;

S5: bonding a connecting bridge 106 on the second side 1013 of the adapter plate, the connecting bridge 106 being electrically connected to the adapter plate 101 to interconnect the encapsulants 104, forming an interconnect encapsulant 108;

S6: a substrate 110 is provided, an interconnect encapsulant 108 is bonded to the substrate 110, and a second side 1013 of the adapter plate is electrically connected to the substrate 110.

The following method of preparing the 2.5D encapsulated structure described in connection with the accompanying drawings is further described as follows:

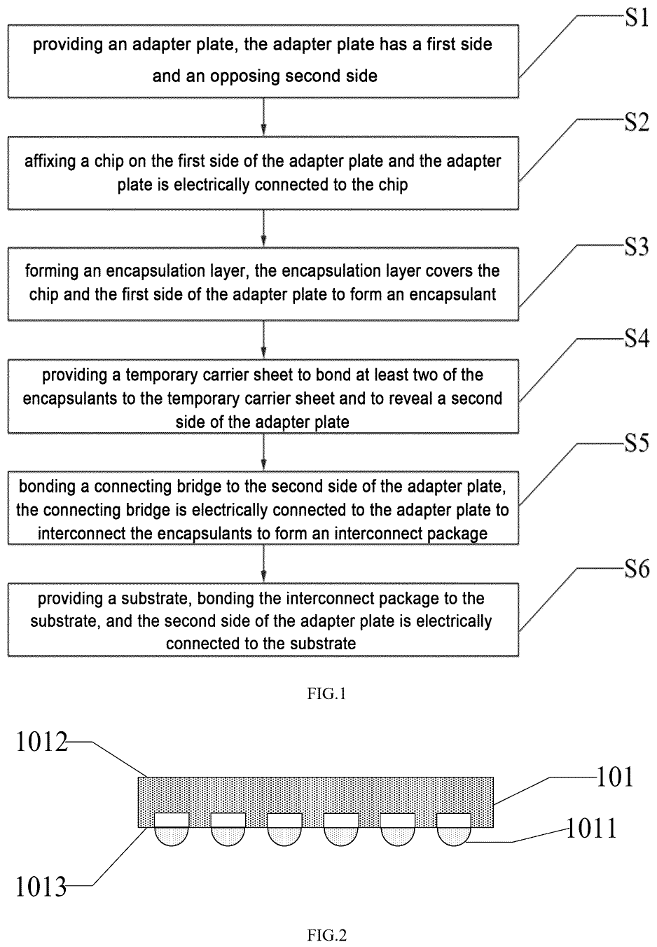

In step S1, referring to FIGS. 1 and 2, an adapter plate 101 is provided, the adapter plate 101 comprising a first face 1012 and an opposite second face 1013.

Optionally, the adapter plate 101 is one of a fiberglass adapter plate, a resin adapter plate, or a silicone-based adapter plate, which may be round, square, or any other desired shape.

Specifically, in this embodiment, the adapter plate 101 is selected to be a silicon-based adapter plate, which generally acts as a bridge between the plurality of dies and the circuit board, thereby accomplishing a heterogeneous integrated package. Wherein a first pad (not shown in the figure) is formed on the first face 1012 and a second pad (not shown in the figure) is formed on the second face 1013, the first pad and the second pad being electrically connected to each other.

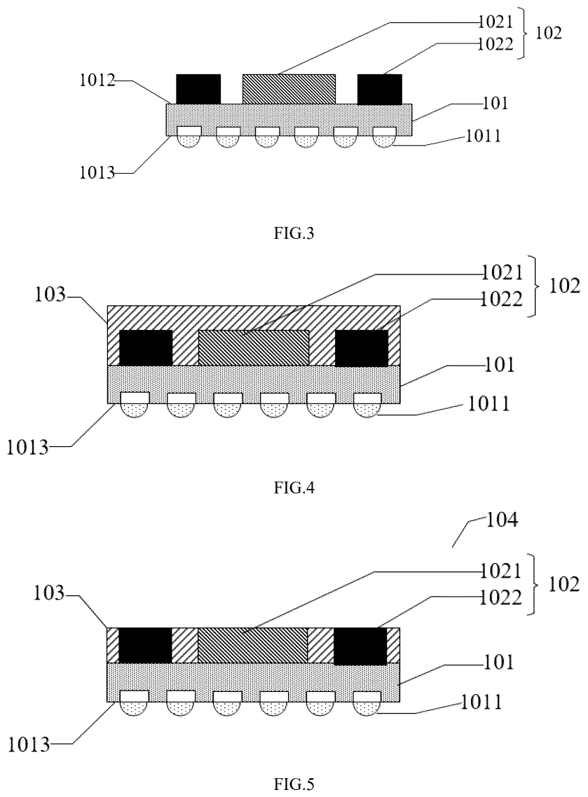

In step S2, referring to FIGS. 1 and 3, a chip 102 is affixed to the first side 1012 of the adapter plate and the adapter plate 101 is electrically connected to the chip 102.

Optionally, the chip 102 comprises a first chip 1021 and a second chip 1022, and the second chip 1022 is symmetrically distributed on both sides of the first chip 1021, the first chip 1022 comprises one of a single bare chip, a multiple bare chip, an integrated circuit (ASIC) chip, or a system-on-chip (SOC) chip, and the second chip 1022 comprises a single bare chip, multiple bare chips, one of a high broadband memory (HBM) chip.

Specifically, in this embodiment, the chip 102 is inverted one-to-one on the first side 1012 of several the adapter plates 101, and the chip 102 is electrically connected one-to-one to the first pads. The first chip 1021 is a system-on-chip (SOC) chip and the second chip 1022 is a high broadband memory (HBM) chip. Of course, in other examples, the type of the chip 102 may also be other semiconductor chip suitable for packaging, and the first chip 1021 and the second chip 1022 may be a plurality of chips of the same type or a plurality of chips of different types, which are not strictly limited in this embodiment.

In step S3, referring to FIGS. 1 and 4, an encapsulation layer 103 is formed, the encapsulation layer 103 covering the chip 102 and the first side 1012 of the adapter plate, forming an encapsulant 104.

Optionally, as shown in FIG. 4, the thickness of the encapsulation layer 103 is larger than the thickness of the chip 102, facilitating the material of the encapsulation layer 103 to completely cover the chip 102. The process for forming the encapsulation layer 103 includes one of a compression molding process, a transfer molding process, a liquid sealant curing and molding process, a vacuum lamination process, and a spin-coating process; the encapsulation layer 103 includes one of an epoxy resin layer, a polyimide layer, and a silicone layer.

Optionally, as shown in FIG. 5, the step of forming the encapsulation layer 103 is followed by the step of performing a planarizing process on the encapsulation layer 103 to reveal the chip layer102. A planarizing process is carried out after the formation of the encapsulation layer 103 in order to maintain a suitable thickness of the encapsulation structure, which is conducive to reducing the size of the encapsulation structure and improving the encapsulation quality of the subsequently formed an encapsulant 104.

Specifically, the planarizing process may comprise a grinding process, a chemical mechanical polishing (CMP) process, a dry grinding process, an etching process, a dicing process, one or more other applicable processes, or a combination thereof. Following the planarizing process, the surface of the encapsulation layer 103 is substantially flush with the surface of the chip 102. As shown in FIG. 5, the encapsulation layer 103 covers the chip 102 and the first side 1012 of the adapter plate to form an encapsulant 104. The encapsulant 104 includes the encapsulation layer 103, the chip 102, and the adapter plate 101.

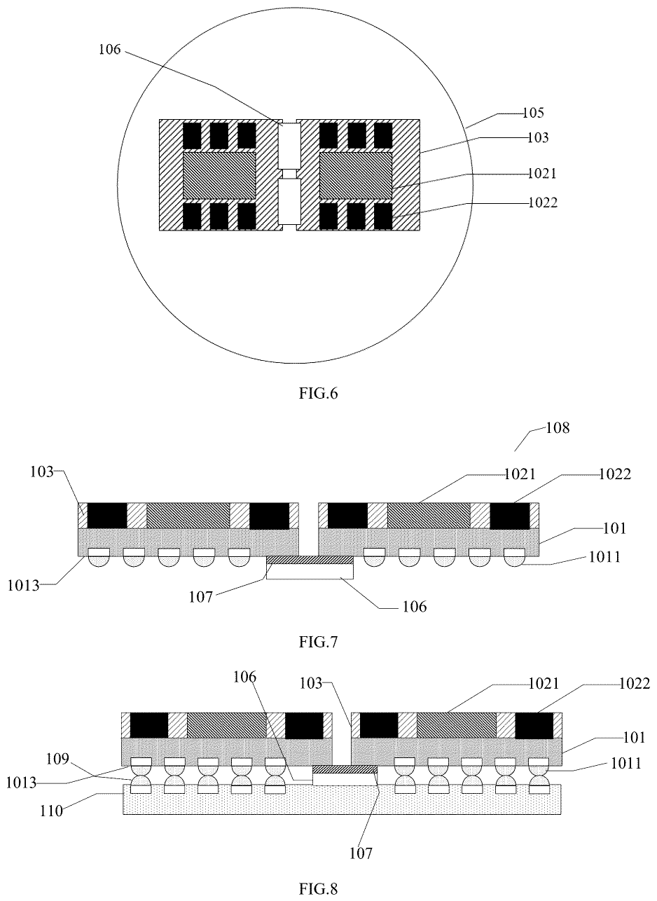

In step S4, referring to FIGS. 1 and 6, a temporary carrier sheet 105 is provided, at least two of the encapsulants 104 are bonded to the temporary carrier sheet 105, and a second side 1013 of the adapter plate is revealed.

Optionally, the temporary carrier 105 may be a flat wafer, a blue film, or other material capable of accomplishing the same function to bond at least two of the encapsulants 104 to the temporary carrier 105 and to reveal the second side 1013 of the adapter plate. Wherein, the number of the encapsulants 104 may be two or more, and the arrangement may be set flexibly and is not limited herein. In addition, the temporary carrier sheet 105 may be removed after forming the connecting bridge 106 and prior to bonding the substrate 110, or will be removed after bonding the substrate 110.

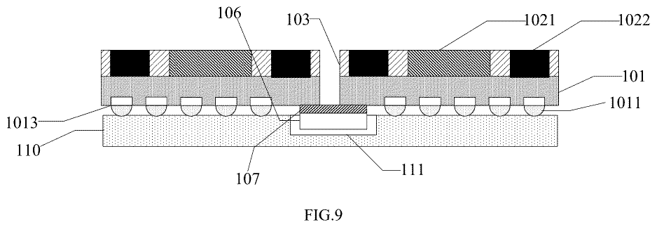

In step S5, referring to FIGS. 1 and 7, a connecting bridge 106 is bonded to the second side 1013 of the adapter plate 101, and the connecting bridge 106 is electrically connected to the adapter plate 101 to interconnect the encapsulants 104, forming an interconnect encapsulant 108.

Specifically, as shown in FIG. 7, after temporarily bonding the encapsulants 104 to the temporary carrier 105, a second side 1013 of the adapter plate 101 is exposed, the connecting bridge 106 is bonded to the second side 1013 of the adapter plate 101, and the connecting bridge 106 is disposed between a plurality of the encapsulants 104 such that the plurality of encapsulants 104 can be electrically connected to each other through the connecting bridge 106 to form an interconnect encapsulant 108. The encapsulant 104 are to electrically interconnected by the connection bridge 106 to form the interconnect encapsulant 108, which can electrically connect small-sized adapter plates to each other to form large-sized adapter plates to achieve increased bandwidth and reduced inter-chip delay, and at the same time to reduce the difficulty of preparing large-sized adapter plates, thereby reducing costs, and improving yields. The structure, material, etc., of the connecting bridge 106 are not limited herein.

Optionally, the size of the connecting bridge 106 may be from 50 to 100 μm, for example, it may be 50 μm, 75 μm or 100 μm, etc., and the method of bonding the connecting bridge 106 may include adhesive bonding, ultrasonic bonding, or thermocompression bonding process, and preferably a thermocompression bonding process in this embodiment which has the advantages of simplicity and high bonding strength.

Optionally, the connecting bridge 106 comprises a glass connecting bridge and/or a silicon connecting bridge. In this embodiment, a glass bridge that can be applied to a small-size packaging process is preferred, because it helps to improve the performance of the semiconductor packaging structure and facilitates the control of costs.

Optionally, a metal wiring layer 107 may also be formed above the connecting bridge 106 to enable the connecting bridge 106 to be electrically connected to the adapter plate 101, thereby interconnecting the encapsulant 104 and ultimately forming an interconnect encapsulant 108. The material of the metal wiring layer 107 is one or a combination of copper, aluminum, nickel, gold, silver, and titanium, and in this embodiment, the material of the metal wiring layer 107 is preferably copper, because a copper block not only has good electrical conductivity, but also has very good ductility, so setting the copper sheet between the connecting bridge 106 and the adapter plate 101 helps to improve the electrical conductivity of the semiconductor packaging structure performance.

In step S6, referring to the steps of FIG. 1 and FIG. 8, a substrate 110 is provided, the interconnect encapsulant 108 is bonded to the substrate 110, and a second side 1013 of the adapter plate is electrically connected to the substrate 110.

Optionally, one or a combination of the second side 1013 of the adapter plate 101 and the surface of the substrate 110 is formed with a metal interconnect 109, the step of bonding the interconnect encapsulant 108 and the substrate 110 comprises a reflow process or a hot press bonding process.

Specifically, referring to FIG. 8, the metal interconnects 109 are formed on the second side 1013 of the adapter plate 101 and on the surface of the substrate 110 to realize the bonded electrical connection of the interconnect encapsulant 108 to the substrate 110, respectively, but not limited thereto, such as the metal interconnects109 may also be formed on the second side 1013 of the adapter plate 101 to realize the electrical connection of the interconnect encapsulant 108 to the substrate 110, as in FIG. 9, or the metal interconnects 109 may be formed on the surface of the substrate 110 to realize the electrical connection of the substrate 110 to the interconnect encapsulant 108.

Optionally, the metal interconnect 109 comprises metal bumps, solder balls, or pads. The material of the metal interconnect 109 is one or a combination of copper, aluminum, nickel, gold, silver, and titanium.

Specifically, in this embodiment, the material of the metal interconnecting member 109 is preferably a combination of copper and nickel, because copper balls not only have good electrical conductivity, but also have very good ductility and are easy to be formed into balls, etc., and setting nickel sheets between the metal interconnecting members 109 formed of copper and the adapter plate 101 helps to improve the electrical conductivity of the semiconductor package structure. Of course, in other examples, the metal interconnects 109 may also be electrically connected to the adapter plate 101 in other ways, which are not strictly limited in this embodiment.

Optionally, the bonding process of the interconnect encapsulant 108 to the substrate 110 comprises a reflow process or a hot press bonding process. Preferred in this embodiment is a hot press bonding process.

Optionally, the substrate 110 comprises one of a non-metallic material such as a silicon oxide substrate, a glass substrate, a ceramic substrate, a polymer substrate, etc., and may have a shape of a circle, a square, or any other desired shape.

Wherein the metal interconnections 109 are formed on the substrate 110 and the metal interconnections 109 are to be disposed in corresponding contact to thereby form a receptacle space, the thickness of this receptacle space being greater than or equal to that of the connecting bridge 106.

Optionally, as shown in FIG. 9, prior to bonding the interconnect encapsulant 108 to the substrate 110, a step of forming a recess 111 in the substrate 110 is included to accommodate the connecting bridge 106 through the recess 111, wherein the method of forming the recess 111 includes a laser drilling process.

Specifically, as desired, when the gap between the adapter plate 101 and the substrate 110 after bonding is difficult to accommodate the connecting bridge 106, recesses 109 may additionally be formed within the substrate 110 to accommodate the connecting bridge 106 through the recesses 111, which may enable a reduction in the thickness of the encapsulation structure and contribute to the improvement of the encapsulation quality. The method of forming the recess 110 may comprise a laser drilling process with good process accuracy and controllability so it does not affect other structures. Of course, the method of forming the recess 110 is not limited to this.

Optionally, the substrate 110 is electrically connected to the connection bridge 106.

Specifically, when the substrate 110 is electrically connected to the connecting bridge 106, the electrical connection between the interconnect encapsulant 108 and the substrate 110can be carried out directly through the connecting bridge 106 as an intermediary, so that the transmission path can be effectively shortened, the degree of integration can be improved, and the problem of space yielding due to the setting of the connecting bridge 106 can be avoided.

### Embodiment 2

As shown in FIG. 8, this embodiment provides a 2.5D package structure which comprises:
an adapter plate 101 comprising a first side 1012 and an opposite second side 1013;
a chip 102 disposed on a first side 1012 of the adapter plate 101 and the adapter plate 101 is electrically connected to the chip 102;
an encapsulation layer 103 covering the chip 102 and the first side 1012 of the adapter plate 101, and the combination of the adapter plate 101, the chip 102, and the encapsulation layer 103 constitutes an encapsulant 104;
a connection bridge 106 disposed on the second side 1013 of the adapter plate 101, the connection bridge 106 is electrically connected to the adapter plate 101 to interconnect the encapsulant 104, and interconnected the encapsulant 104 in combination with the connection bridge 106 constitutes an interconnected encapsulant 108; and
a substrate 110 disposed below the interconnect encapsulant 108 and the second side 1013 of the adapter plate 101 being electrically connected to the substrate 110.

Optionally, as shown in FIG. 7, the connecting bridge 106 is a silicon bridge and/or a glass bridge in this embodiment, the connecting bridge 106 is preferred to be a glass bridge in order to reduce manufacturing costs.

Optionally, as shown in FIG. 9, the substrate 110 is further provided with a recess 111 for accommodating the connection bridge 106.

In summary, the 2.5D package structure and preparation method provided by the present invention first prepares a package body including an adapter plate, a chip, and an encapsulation layer electrically connected to each other, then electrically connects the independently set packages to form an interconnected package body by means of connecting bridges and then electrically connects them to the substrate, so that a plurality of small-sized adapter plates can be electrically connected to each other by means of the connecting bridge to form a large-sized adapter plate, thus realizing bandwidth increase and reducing the delay between chips, and by reducing the difficulty of preparing large-sized adapter plates, costs are reduced, and yields improved. The bridge can electrically connect multiple small-sized adapter plates to each other to form a large adapter plate, so effectively addresses the limitations of existing technologies, making it highly valuable for industrial applications.

The embodiments described above serve merely as illustrative examples of the principles and effects of the present invention, and are not intended to serve as limitations on the present invention. Persons skilled in the art may modify or alter these embodiments without departing from the spirit and scope of the present disclosure. Accordingly, all equivalent modifications or alterations accomplished by persons having ordinary knowledge of the art without departing from the spirit and technical ideas disclosed herein shall still be covered by the claims of the present invention.

1. A method of preparing a 2.5D encapsulated structure, comprising steps of:
providing an adapter plate, wherein the adapter plate has a first side and an opposing second side;
affixing chips on the first side of the adapter plate and electrically connecting the chips to the adapter plate;
forming an encapsulation layer, therein the encapsulation layer covers the chips and the first side of the adapter plate to form encapsulants;
providing a temporary carrier sheet to bond at least two of the encapsulants to the temporary carrier sheet, wherein the second side of the adapter plate is exposed;
bonding a connecting bridge to the second side of the adapter plate, wherein the connecting bridge is electrically connected to the adapter plate to interconnect the at least two of the encapsulants to form an interconnect package;
providing a substrate; and
bonding the interconnect package to the substrate, and electrically connecting the second side of the adapter plate to the substrate.

2. The method of preparing the 2.5D encapsulated structure according to claim 1, further comprising, prior to bonding the interconnect package to the substrate, a step of forming a recess in the substrate to accommodate the connecting bridge through the recess, wherein the step of forming the recess comprises a laser drilling process.

3. The method of preparing the 2.5D encapsulated structure according to claim 1, wherein the connecting bridge comprises a glass connecting bridge and/or a silicon connecting bridge, and wherein the step of bonding the connecting bridge comprises a hot press bonding process.

4. The method of preparing the 2.5D encapsulated structure according to claim 1, wherein one or a combination of the second side of the adapter plate and a surface of the substrate is formed with a metallic interconnect, and wherein the step of bonding the interconnect package to the substrate comprises a reflow process or a hot press bonding process.

5. The method of preparing the 2.5D encapsulated structure according to claim 1, wherein the connecting bridge is electrically connected to the substrate.

6. The method of preparing the 2.5D encapsulated structure according to claim 1, further comprising performing a planarizing process on the encapsulation layer to expose the chips following forming the encapsulation layer.

7. The method of preparing the 2.5D encapsulated structure according to claim 1, further comprising a step of removing the temporary carrier sheet, after forming the connecting bridge and before or after bonding the substrate.

8. A 2.5D package structure comprising:
an adapter plate having a first side and an opposing second side;
chips disposed on the first side of the adapter plate, wherein the chips are electrically connected to the first side of the adapter plate;
an encapsulation layer, covering the chips and the first side of the adapter plate, wherein the adapter plate, the chips, and the encapsulation layer combine to form encapsulants;
a connecting bridge formed on the second side of the adapter plate, wherein the connecting bridge is electrically connected to the adapter plate to interconnect the encapsulants, and wherein the connecting bridge interconnects the encapsulants and constitutes an interconnect package; and
a substrate disposed below the interconnect package and the second side of the adapter plate, wherein the second side of the adapter plate is electrically connected to the substrate.

9. The 2.5D package structure according to claim 8, wherein the connecting bridge is one or a combination of a silicon bridge or a glass bridge.

10. The 2.5D package structure according to claim 8, wherein the substrate is further provided with a recess for accommodating the connection bridge.
